(19) United States
(12) Patent Application Publication
(10) Pub. No.: US 2019/0312090 A1
(43) Pub. Date: Oct. 10, 2019

(54) ELECTRONIC DEVICE INCLUDING BENDABLE DISPLAY

(71) Applicant: Samsung Electronics Co., Ltd., Gyeonggi-do (KR)

(72) Inventors: Jungsik PARK, Gyeonggi-do (KR); Jungchul An, Gyeonggi-do (KR); Hyungsup Byeon, Gyeonggi-do (KR)

(73) Assignee: Samsung Electronics Co., Ltd.

(21) Appl. No.: 16/376,747

(22) Filed: Apr. 5, 2019

(30) Foreign Application Priority Data
Apr. 6, 2018 (KR) 10-2018-0040277

(51) Int. Cl. H01L 27/32; G06F 3/041; G06F 1/16; G09G 3/3225

(52) U.S. Cl. CPC H01L 27/323; G06F 3/0412; G09G 2310/0264; G09G 3/3225; G06F 1/1643

(57) ABSTRACT

An electronic device is provided. The electronic device includes a pixel layer including a plurality of pixels, a substrate including a first area, and a second area, a display driver integrated circuit (DDI) configured to apply a signal to the pixel layer, and one or more wiring layers disposed on the substrate. The substrate includes a planar zone including at least a portion of the first area and at least a portion of the second area, and a bending zone extending from the at least a portion of the second area. A bending start point of the bending zone is adjacent to the second point, and the one or more wiring layers are disposed in at least a portion of the planar zone and at least a portion of the bending zone.

### CROSS-REFERENCE TO RELATED APPLICATION(S)

This application is based on and claims priority under 35 U.S.C. § 119 to Korean Patent Application Serial No. 10-2018-0040277, filed on Apr. 6, 2018, in the Korean Intellectual Property Office, the entire disclosure of which is incorporated herein by reference.

### BACKGROUND

### 1. Field

The present disclosure relates generally to an electronic device including a display panel with a rounded corner.

### 2. Description of Related Art

With the growth of mobile communication technology and processor technology, electronic devices (e.g., portable or mobile devices) are now capable of performing a great variety of functions in addition to a traditional telephony function. Further, in order to visually offer such functions to the user, the electronic device may be equipped with a display in general.

Recent electronic devices such as smart phones tend to have a large-sized display. According to this tendency, the front surface of the electronic device may be mostly occupied by the display.

In addition, the electronic devices are being developed in various forms of outer appearance to meet various demands of users. One recently developed device is implemented in a rounded rectangular form. However, compared with a normal rectangular form, this rounded form may make it difficult to efficiently enlarge the area of the display on the front and/or lateral surface(s) of the electronic device.

### SUMMARY

The present disclosure has been made to address at least the disadvantages described above and to provide at least the advantages described below.

In accordance with an embodiment of the present disclosure, an electronic device is provided. The electronic device includes a pixel layer including a plurality of pixels, a substrate including a first area in which the pixel layer is disposed, and a second area extending outward from the first area; a display driver integrated circuit (DDI) configured to apply a signal to the pixel layer, and one or more wiring layers disposed on the substrate and electrically connected between the DDI and the pixel layer. The substrate may include a planar zone including at least a portion of the first area and at least a portion of the second area, and a bending zone extending from the at least a portion of the second area. The at least a portion of the second area may include a third area in which a first point of an outline of the planar zone is spaced apart from the first area by a first distance, and a fourth area in which a second point of the outline is spaced apart from the first area by a second distance being smaller than the first distance. A bending start point of the bending zone may be adjacent to the second point, and the one or more wiring layers may be disposed in at least a portion of the planar zone and at least a portion of the bending zone.

According to an embodiment of the present disclosure, an electronic device is provided. The electronic device includes a pixel layer including a plurality of pixels, a display panel including a first area in which the pixel layer is disposed, and a second area extending outward from the first area, a touch panel formed on the display panel, a DDI configured to apply a signal to the pixel layer, and one or more wiring layers disposed on the display panel and electrically connected between the DDI and the pixel layer. The display panel may include a planar zone including at least a portion of the first area and at least a portion of the second area, and a bending zone extending from the at least a portion of the second area, and the at least a portion of the second area may include a third area in which a first point of an outline of the planar zone is spaced apart from the first area by a first distance, and a fourth area in which a second point of the outline is spaced apart from the first area by a second distance being smaller than the first distance. A bending start point of the bending zone may be adjacent to the second point, and the one or more wiring layers may be disposed in at least a portion of the planar zone and at least a portion of the bending zone.

### BRIEF DESCRIPTION OF THE DRAWINGS

The above and other aspects, features and advantages of certain embodiments of the disclosure will be more apparent from the following detailed description taken in conjunction with the accompanying drawings, in which:

FIG. 1 is a diagram illustrating an electronic device in a network environment, according to an embodiment;

FIG. 2A is a diagram illustrating a front surface of a mobile electronic device, according to an embodiment;

FIG. 2B is a diagram illustrating a rear surface of an electronic device, according to an embodiment;

FIG. 3 is a diagram illustrating an electronic device, according to an embodiment;

FIG. 4 is a diagram illustrating a stack structure of a display, according to an embodiment;

FIG. 5 is a diagram illustrating a display panel structure of an electronic device, according to an embodiment;

FIG. 6 is a diagram illustrating a left lower portion of an electronic device, according to an embodiment;

FIG. 7 is a diagram illustrating a display panel structure of an electronic device, according to an embodiment; and

FIG. 8 is a diagram illustrating a display device including a bendable display, according to an embodiment.

### DETAILED DESCRIPTION

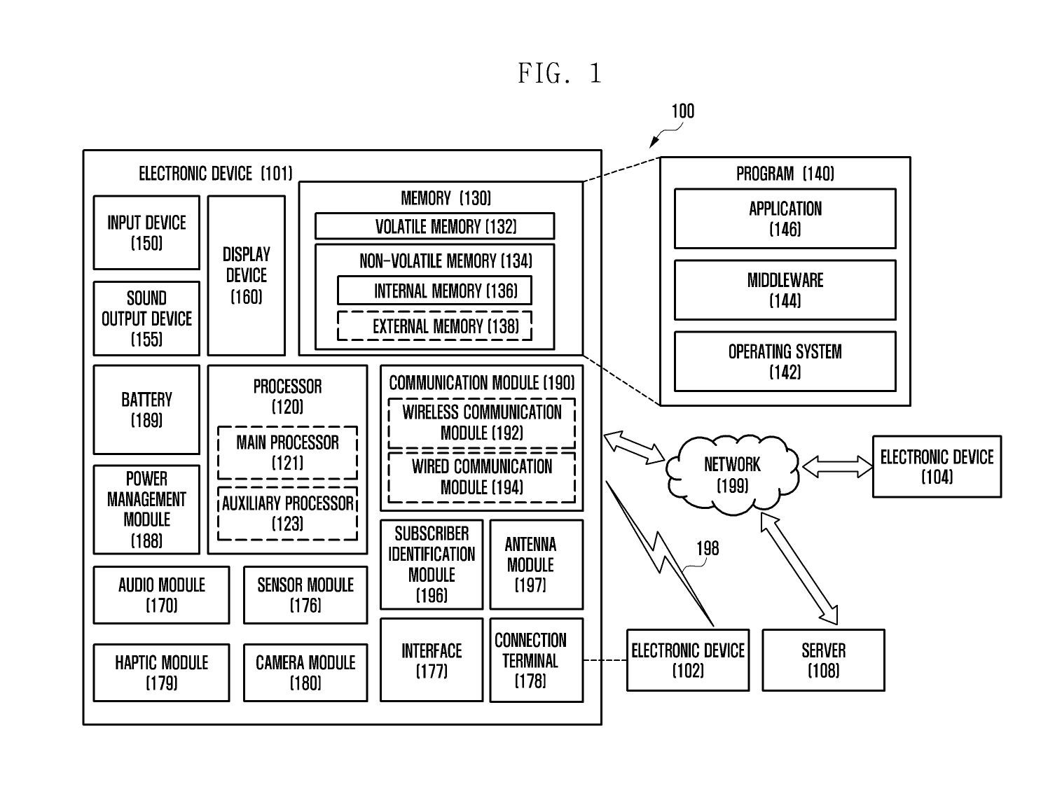

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. The electronic device 101 may include a processor 120, memory 130, an input device 150, a sound output device 155, a display device 160, an audio module 170, a sensor module 176, an interface 177, a haptic module 179, a camera module 180, a power management module 188, a battery 189, a communication module 190, a subscriber identification module (SIM) 196, or an antenna module 197. In some embodiments, at least one (e.g., the display device 160 or the camera module 180) of the components may be omitted from the electronic device 101, or one or more other components may be added in the electronic device 101. Some of the components may be implemented as single integrated circuitry. For example, the sensor module 176 (e.g., a fingerprint sensor, an iris sensor, or an illuminance sensor) may be implemented as embedded in the display device 160 (e.g., a display).

The processor 120 may execute, for example, software (e.g., a program 140) to control at least one other component (e.g., a hardware or software component) of the electronic device 101 coupled with the processor 120, and may perform various data processing or computation. As at least part of the data processing or computation, the processor 120 may load a command or data received from another component (e.g., the sensor module 176 or the communication module 190) in volatile memory 132, process the command or the data stored in the volatile memory 132, and store resulting data in non-volatile memory 134. The processor 120 may include a main processor 121 (e.g., a central processing unit (CPU) or an application processor (AP)), and an auxiliary processor 123 (e.g., a graphics processing unit (GPU), an image signal processor (ISP), a sensor hub processor, or a communication processor (CP)) that is operable independently from, or in conjunction with, the main processor 121. Additionally or alternatively, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display device 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). The auxiliary processor 123 (e.g., an ISP or a CP) may be implemented as part of another component (e.g., the camera module 180 or the communication module 190) functionally related to the auxiliary processor 123.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input device 150 may receive a command or data to be used by another component (e.g., the processor 120) of the electronic device 101, from the outside (e.g., a user) of the electronic device 101. The input device 150 may include, for example, a microphone, a mouse, or a keyboard.

The sound output device 155 may output sound signals to the outside of the electronic device 101. The sound output device 155 may include, for example, a speaker or a receiver. The speaker may be used for general purposes, such as playing multimedia or playing record, and the receiver may be used for an incoming calls. The receiver may be implemented as separate from, or as part of the speaker.

The display device 160 may visually provide information to the outside (e.g., a user) of the electronic device 101. The display device 160 may include, for example, a display, a hologram device, or a projector and control circuitry to control a corresponding one of the display, hologram device, and projector. The display device 160 may include touch circuitry adapted to detect a touch, or sensor circuitry (e.g., a pressure sensor) adapted to measure the intensity of force incurred by the touch.

The audio module 170 may convert a sound into an electrical signal and vice versa. According to an embodiment, the audio module 170 may obtain the sound via the input device 150, or output the sound via the sound output device 155 or a headphone of an external electronic device (e.g., an electronic device 102) directly (e.g., wired) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. The sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humiditor, or an illuminance sensor.

The interface 177 may support one or more specified protocols to be used for the electronic device 101 to be coupled with the external electronic device 102 directly (e.g., wired) or wirelessly. The interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device 102. The connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. The haptic module 179 may include, for example, a motor, a piezoelectric element, or an electric stimulator.

The camera module 180 may capture a still image or moving images. The camera module 180 may include one or more lenses, image sensors, ISPs, or flashes.

The power management module 188 may manage power supplied to the electronic device 101. The power management module 188 may be implemented as at least part of, for example, a power management integrated circuit (PMIC).

The battery 189 may supply power to at least one component of the electronic device 101. The battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently from the processor 120 (e.g., the AP) and supports a direct (e.g., wired) communication or a wireless communication. The communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or Infrared Data Association (IrDA)) or the second network 199 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The antenna module 197 may transmit or receive a signal or power to or from the outside (e.g., the external electronic device) of the electronic device 101. The antenna module 197 may include one or more antennas, and, therefrom, at least one antenna appropriate for a communication scheme used in the communication network, such as the first network 198 or the second network 199, may be selected, for example, by the communication module 190 (e.g., the wireless communication module 192). The signal or the power may then be transmitted or received between the communication module 190 and the external electronic device via the selected at least one antenna.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 and 104 may be a device of a same type as, or a different type, from the electronic device 101. All or some of operations to be executed at the electronic device 101 may be executed at one or more of the external electronic devices 102,104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, or client-server computing technology may be used, for example.

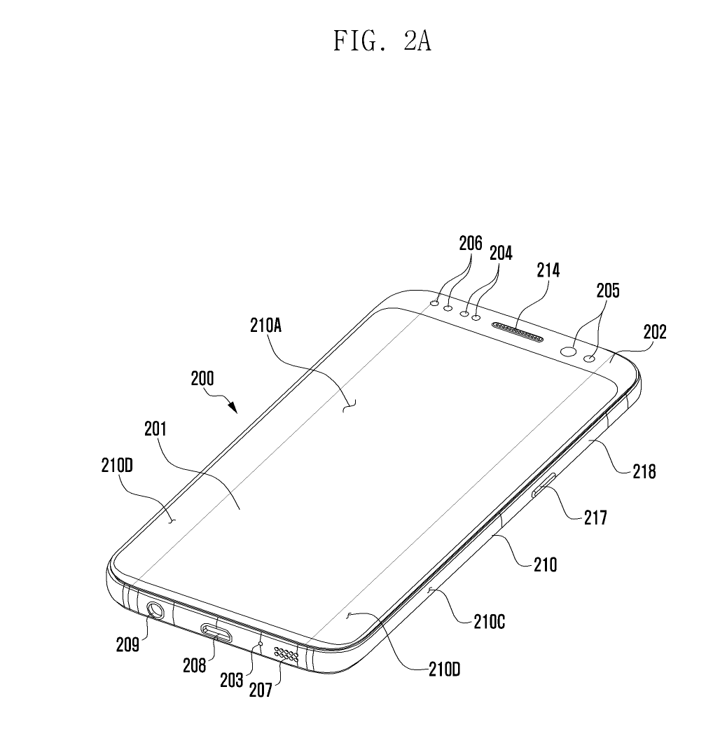

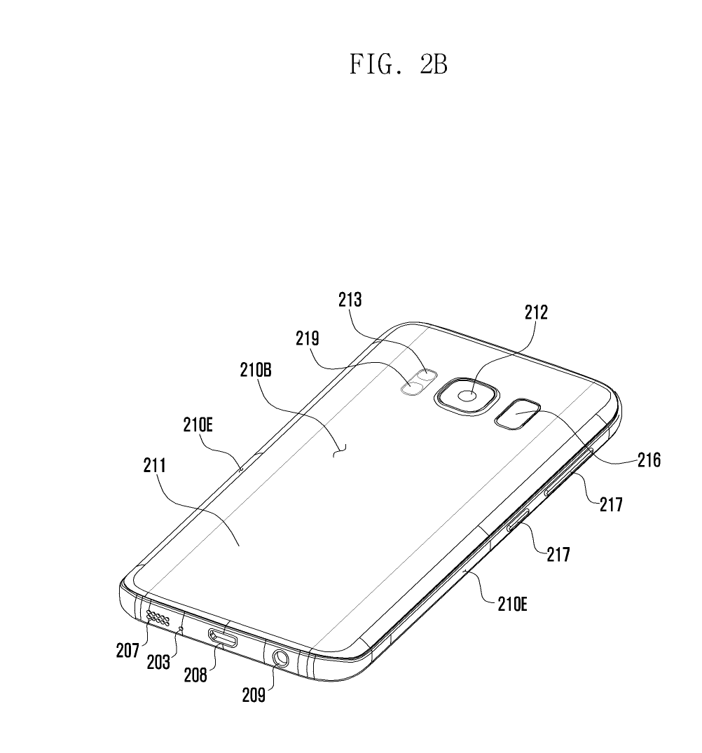

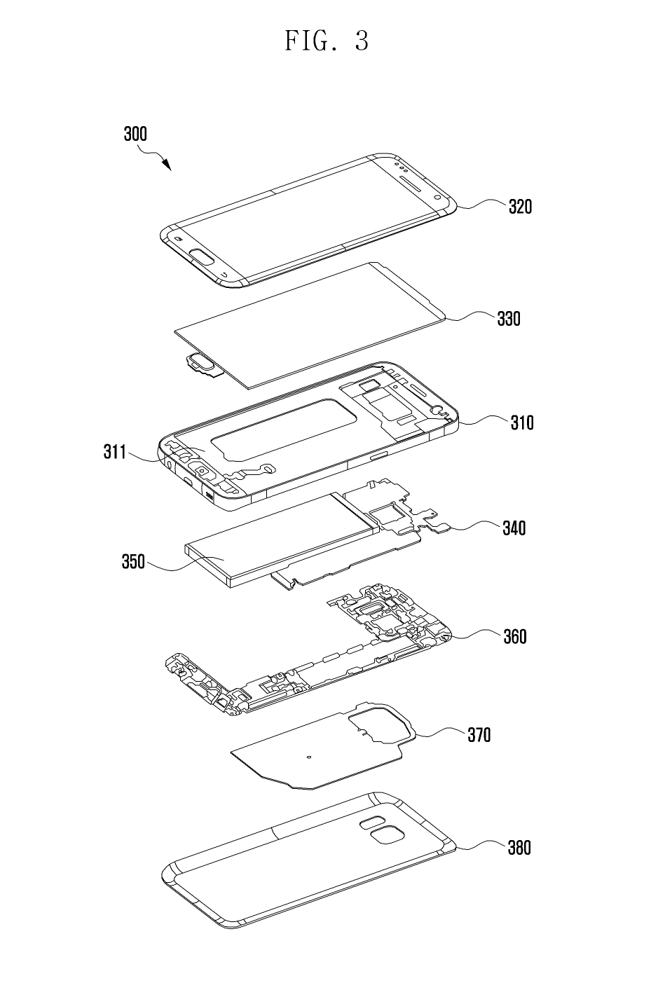

FIG. 2A is a diagram illustrating a front surface of a mobile electronic device, according to an embodiment. FIG. 2B is a diagram illustrating a rear surface of the electronic device of FIG. 2A, according to an embodiment. FIG. 3 is a diagram illustrating the electronic device of FIG. 2A, according to an embodiment.

Referring to FIGS. 2A and 2B, the electronic device 200 may include a housing 210 that includes a first surface (or front surface) 210A, a second surface (or rear surface) 210B, and a lateral surface 210C that surrounds a space between the first surface 210A and the second surface 21013. The housing may refer to a structure that forms a part of the first surface 210A, second surface 210B, and lateral surface 210C as shown in FIG. 2A. The first surface 210A may be formed of a front plate 202 (e.g., a glass plate or polymer plate coated with a variety of coating layers) at least a part of which is substantially transparent. The second surface 210B may be formed of a rear plate 211 which is substantially opaque. The rear plate 211 may be formed of coated or colored glass, ceramic, polymer, metal (e.g., aluminum, stainless steel (STS), or magnesium), or any combination thereof. The lateral surface 210C may be formed of a lateral bezel structure (or lateral member) 218 which is combined with the front plate 202 and the rear plate 211 and includes a metal and/or polymer. The rear plate 211 and the lateral bezel structure 218 may be integrally formed and may have the same material (e.g., a metallic material such as aluminum).

The front plate 202 may include two first regions 210D disposed at long edges thereof, respectively, and bent and extended seamlessly from the first surface 210A toward the rear plate 211. Similarly, the rear plate 211 may include two second regions 210E disposed at long edges thereof, respectively, and bent and extended seamlessly from the second surface 210B toward the front plate 202. The front plate 202 (or the rear plate 211) may include only one of the first regions 210D (or of the second regions 210E). The first regions 210D or the second regions 210E may not be included in part. When viewed from a lateral side of the electronic device 200, the lateral bezel structure 218 may have a first thickness (or width) on a lateral side where the first or second region 210D or 210E is not included, and may have a second thickness, being smaller than the first thickness, on another lateral side where the first or second region 210D or 210E is included.

The electronic device 200 may include at least one of a display 201, audio modules 203, 207, and 214, sensor modules 204, 216, and 219, camera modules 205, 212, and 213, a key input device 217, a light emitting device 206, and connector holes 208 and 209. The electronic device 200 may omit at least one (e.g., the key input device 217 or the light emitting device 206) of the above components, or may further include any other component.

The display 201 may be exposed through a substantial portion of the front plate 202. At least a part of the display 201 may be exposed through the front plate 202 that forms the first surface 210A and the first region 210D of the lateral surface 210C. Outlines (i.e., edges and corners) of the display 201 may have the substantially same form as those of the front plate 202. The spacing between the outline of the display 201 and the outline of the front plate 202 may be substantially unchanged in order to enlarge the exposed area of the display 201.

A recess or opening may be formed in a portion of a display area of the display 201 to accommodate at least one of the audio module 214, the sensor module 204, the camera module 205, and the light emitting device 206. At least one or the audio module 214, the sensor module 204, the camera module 205, the fingerprint sensor 216, and the light emitting element 206 may be disposed on the back of the display area of the display 201. The display 201 may be combined with or adjacent to a touch sensing circuit, a pressure sensor capable of measuring the touch strength (pressure), and/or a digitizer for detecting a stylus pen. At least a part of the sensor modules 204 and 219 and/or at least a part of the key input device 217 may be disposed in the first region 210D and/or the second region 210E.

The audio modules 203, 207 and 214 may correspond to a microphone hole 203 and speaker holes 207 and 214. The microphone hole 203 may contain a microphone disposed therein for acquiring external sounds and, in any case, contain a plurality of microphones to sense a sound direction. The speaker holes 207 and 214 may be classified into an external speaker hole 207 and a call receiver hole 214. Such holes 203, 207 and 214 may be implemented as a single hole, or a speaker (e.g., a piezo speaker) may be provided without the speaker holes 207 and 214.

The sensor modules 204, 216 and 219 may generate electrical signals or data corresponding to an internal operating state of the electronic device 200 or an external environmental condition. The sensor modules 204, 216 and 219 may include a first sensor module 204 (e.g., a proximity sensor) and/or a second sensor module (e.g., a fingerprint sensor) disposed on the first surface 210A of the housing 210, and/or a third sensor module 219 (e.g., a heart rate monitor (HRM) sensor) and/or a fourth sensor module 216 (e.g., a fingerprint sensor) disposed on the second surface 210B of the housing 210. The fingerprint sensor may be disposed on the second surface 210B as well as the first surface 210A (e.g., the display 201) of the housing 210. The electronic device 200 may further include at least one of a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, or an illuminance sensor.

The camera modules 205, 212 and 213 may include a first camera device 205 disposed on the first surface 210A of the electronic device 200, and a second camera device 212 and/or a flash 213 disposed on the second surface 210B. The camera module 205 or 212 may include one or more lenses, an image sensor, and/or an ISP. The flash 213 may include a light emitting diode or a xenon lamp. In some embodiments, two or more lenses (infrared cameras, wide angle and telephoto lenses) and image sensors may be disposed on one side of the electronic device 200.

The key input device 217 may be disposed on the lateral surface 210C of the housing 210. The electronic device 200 may not include some or all of the above-mentioned key input devices 217, and the key input device 217 which is not included may be implemented in any other form such as a soft key on the display 201. The key input device may include the sensor module 216 disposed on the second surface 210B of the housing 210.

The light emitting device 206 may be disposed on the first surface 210A of the housing 210. The light emitting device 206 may provide status information of the electronic device 200 in optical form. The light emitting device 206 may provide a light source associated with the operation of the camera module 205. The light emitting device 206 may include a light emitting device (LED), an IR LED, or a xenon lamp.

The connector holes 208 and 209 may include a first connector hole 208 adapted for a connector (e.g., a USB connector) of transmitting and receiving power and/or data to and from an external electronic device, and/or a second connector hole 209 adapted for a connector (e.g., an earphone jack) of transmitting and receiving an audio signal to and from an external electronic device.

Referring to FIG. 3, the electronic device 300 may include a lateral bezel structure 310, a first support member 311 (e.g., a bracket), a front plate 320, a display 330, a printed circuit board 340, a battery 350, a second support member 360 (e.g., a rear case), an antenna 370, and a rear plate 380. The electronic device 300 may not include at least one (e.g., the first support member 311 or the second support member 360) of the above components or may further include any other component. Some components of the electronic device 300 may be the same as or similar to those of the electronic device 200 shown in FIG. 2A or 2B, so that repeated descriptions are omitted below.

The first support member 311 is disposed inside the electronic device 300 and may be connected to or integrated with the lateral bezel structure 310. The first support member 311 may be formed of a metal material and/or a non-metal (e.g., polymer) material. The first support member 311 may be combined with the display 330 at one side thereof and also combined with the printed circuit board 340 at the other side thereof. On the printed circuit board 340, a processor, a memory, and/or an interface may be mounted.

The printed circuit board 340 may include a main circuit board and a sub circuit board. The main circuit board and the sub circuit board may be disposed under a bracket, and may be electrically coupled to each other through a connector or a wiring layer. The printed circuit board 340 may be implemented as a rigid printed circuit board (rigid PCB) or a flexible printed circuit board (FPCB). The printed circuit board 340 may be a main board, a printed board assembly (PBA), or simply a PCB. On the printed circuit board 340, various electronic components (e.g., a processor, a memory, and the like), elements, printed circuits, etc. may be mounted or arranged.

The processor may include one or more of a CPU, an AP, a GPU, an ISP, a sensor hub processor, or a CP.

The memory may include volatile memory or non-volatile memory.

The interface may include a HDMI, a USB interface, an SD card interface, and/or an audio interface. The interface may electrically or physically connect the electronic device 300 with an external electronic device and may include a USB connector, an SD card/MMC connector, or an audio connector.

The battery 350 is a device for supplying power to at least one component of the electronic device 300, and may include a non-rechargeable primary battery, a rechargeable secondary battery, or a fuel cell. At least a part of the battery 350 may be disposed on the substantially same plane as the printed circuit board 340. The battery 350 may be integrally disposed within the electronic device 300, and may be detachably disposed from the electronic device 300.

The antenna 370 may be disposed between the rear plate 380 and the battery 350. The antenna 370 may include a near field communication (NFC) antenna, a wireless charging antenna, and/or a magnetic secure transmission (MST) antenna. The antenna 370 may perform short-range communication with an external device, or transmit and receive power required for charging wirelessly. An antenna structure may be formed by a part or combination of the lateral bezel structure 310 and/or the first support member 311.

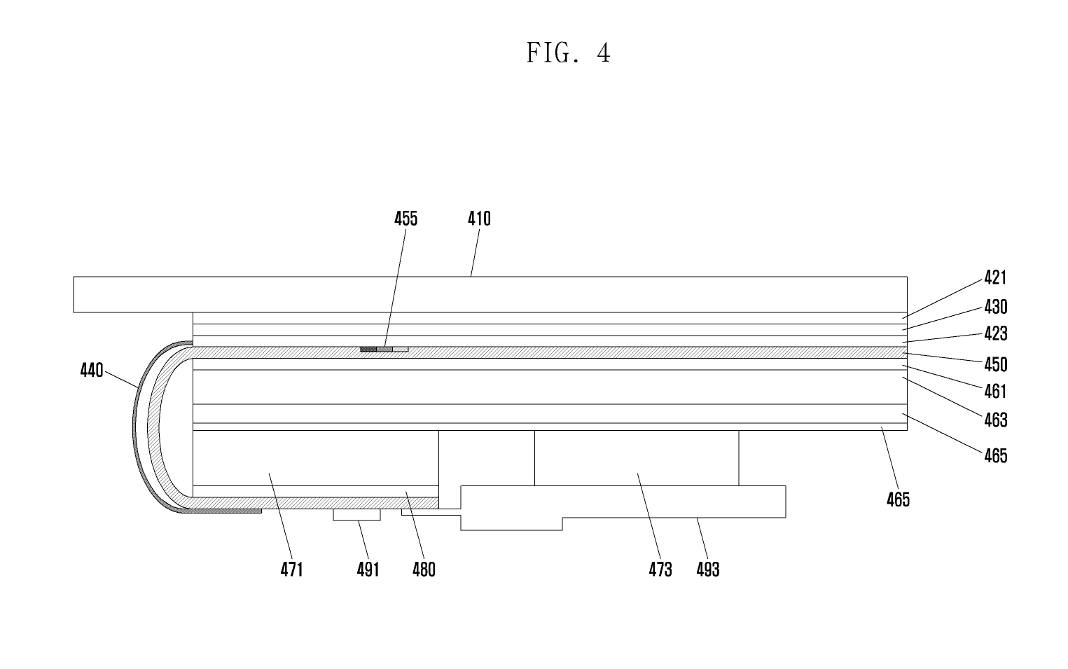

FIG. 4 is a diagram illustrating a stack structure of a display, according to an embodiment.

Referring to FIG. 4, the display may include a first optical clear adhesive (OCA) 421, a second OCA 423, a polarizer 430, a bending protection layer 440, a display panel 450, a first polymer film 461, a second polymer film 480, a first support layer 463, a second support layer 465, a shielding/heat-dissipating layer 465, an adhesive layer 471, a pressure sensor 473, a DDI 491, or a PCB 493.

As shown in FIG. 4, the display may be disposed under the front plate 410. The front plate 410 may transmit light generated by the display. The display may further include a touch panel that detects a change in a physical quantity caused by a touch of an external object, and a user may perform a touch input by touching a part of body (e.g., finger) on the front plate 410. The front plate 410 may be combined with the housing and thereby protect components contained in the housing from dust, water, or any other foreign matter.

The first OCA 421 may be disposed between the polarizer 430 (or the display panel 450) and the front plate 410. In addition, the second OCA 423 may be disposed between the display panel 450 and the polarizer 430.

The polarizer 430 may pass light polarized in a specified direction to improve outdoor visibility. The polarizer 430 may include a poly ethylene terephthalate (PET) film or a tri-acetyl cellulose (TAC) film.

The bending protection layer 440 may be attached to at least a portion of the display panel 450 and protect the portion of the display panel 450 from external impacts. The bending protection layer 440 may be attached to a bending zone and a planar zone of the display panel 450. The bending protection layer 440 may prevent the display panel 450 from being broken or cracked, and also protect a wiring portion of the display panel 450 from being damaged.

The first polymer film 461 and/or the second polymer film 480 may be disposed under the display panel 450. The first polymer film 461 and/or the second polymer film 480 may support the display panel 450 and protect the display panel 450 from external impacts.

The display panel 450 may generate light, based on signals supplied from the DDI 491 through scan lines and data lines.

The display panel 450 may include a pixel layer (i.e., pixel array), an emission driver, and an electrostatic discharge (ESD) protection circuit.

The pixel layer may include a plurality (e.g., millions) of pixels 455. The display may output image data (e.g., image, text, video, etc.), based on light generated from the pixel layer. Each pixel 455 included in the pixel layer may include at least one of a red sub-pixel, a green sub-pixel, or a blue sub-pixel (e.g., RGB, RG, or BG). The pixel layer may be configured in a rounded rectangular shape based on a corner structure of the pixels 455.

The display panel 450 may include an organic light emitting diode. The display panel 450 may include an organic light emitting device, a substrate (e.g., a low temperature poly silicon (LTPS) substrate) on which the organic light emitting device is disposed, and a thin film encapsulation (TFE) for protecting the light emitting device.

The emission driver may control the light emission timing of pixel by applying a light emission control signal (hereinafter, EM signal) to each pixel. The emission driver may be divided into a plurality of blocks. Each block may refer to an emission driving block or an EM block. The emission driver may be included in the display driver integrated circuit 491 instead of the display panel 450.

The ESD protection circuit may protect the display panel 450 from internal or external electrostatic discharge.

The pixel layer may form a display area of the display panel 450. In addition, the emission driver and the ESD protection circuit may be disposed or formed on an inactive area of the display panel 450.

The DDI 491 may apply a driving signal to the display panel 450. The DDI 491 may be electrically coupled to the wiring layers and pixels disposed on the display panel 450. The DDI 491 may receive, from a processor, image data to be outputted through the display, and supply a signal and power corresponding to the image data to the display panel 450.

The DDI 491 may be disposed on the PCB electrically coupled to the display panel 450. The DDI 491 may be disposed at various positions on the PCB of the display panel 450. The DDI 491 may be disposed on another PCB electrically coupled to the display panel 450 instead of the PCB of the display panel 450.

As shown in FIG. 4, the DDI 491 may be disposed in a bending area of the display panel 450. When one portion of the display panel 450 is bent toward a direction opposite to the display area of the display panel and thereby forms the bending area, the DDI 491 may be disposed under the display panel 450 within the bending area as shown in FIG. 4. However, the position of the DDI 491 is not limited to the above and may be varied.

The DDI 491 may include a frame buffer, an image processing unit (IP), a gate driver, a source driver, a timing controller (T-CON), and a pixel power source.

The frame buffer may store image data received from the processor (host). The frame buffer may include a memory space corresponding to a resolution of the image data and the number of color gradations. The image processing unit may improve or correct the quality of the image data provided from the frame buffer. The image processing unit may correct the image data, based on a pixel layout of the pixel layer.

The gate driver and the source driver may generate a signal to be supplied to the display panel under the control of the timing controller.

The gate driver may supply a scan signal (or a gate signal) to each pixel of the display panel 450 through a scan line. The gate driver may control a voltage of a gate of a scan transistor (TFT), based on the scan signal, thereby controlling whether each pixel emits light. The gate driver may be disposed on one side (e.g., the left side) of the display panel 450. The gate driver may be disposed on both sides of the display panel 450 to prevent a voltage drop of the scan signal.

The source driver may supply a data signal (or a source signal) to each pixel of the display panel 450 through a data line. The source driver may control a light emission intensity of each pixel by applying a signal to the data signal.

The T-CON may provide control signals corresponding to image data to the gate driver and the source driver, and may also control the transmission timing of each control signal.

The pixel power source may supply power to generate light at each pixel. The pixel power source may include a DC/DC converter and may supply a voltage (e.g., a first voltage (e.g., ELVDD) and a second voltage (e.g., ELVSS)), obtained by the DC/DC converter, to the pixel.

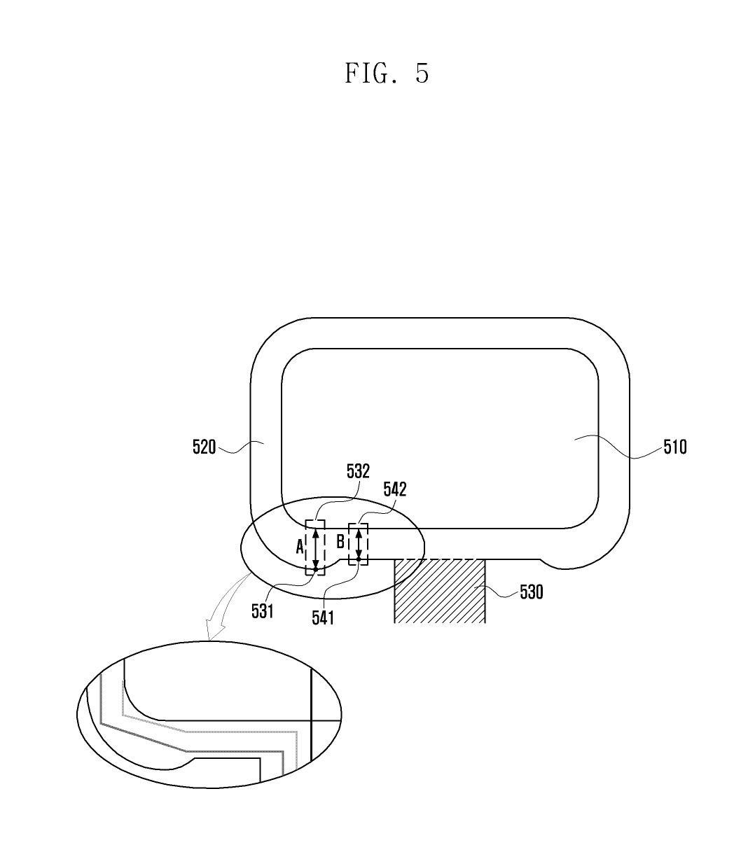

FIG. 5 is a diagram illustrating a display panel structure of an electronic device, according to an embodiment.

The display of the electronic device may include a display area and a non-display area.

The display area may refer to an area where the pixel layer including a plurality of pixels is disposed, which can output image data to the outside of the electronic device. The non-display area may refer to an area other than the display area in the entire display of the electronic device. The non-display area may include a region where a certain circuit element (e.g., a gate driver, an emission driver, and/or the like) and a wiring layer (e.g., a scan line, a data line, an ELVDD wiring layer, an ELVSS wiring layer, and/or the like) are disposed. The non-display area may include a region where the above-discussed DDI for applying a signal to the pixel layer in the display area and/or a wiring layer for electrically connecting the DDI and the pixel layer are/is disposed.

The display panel may include the pixel layer including a plurality of pixels, and a substrate disposed under the pixel layer.

Referring to FIG. 5, the substrate of the display panel may include a first area 510 corresponding to the display area in which the pixel layer is disposed, and a second area 520 extending outward from the first area 510.

The substrate may include a planar zone and a bending zone. At least a portion (e.g., the bending zone) of the substrate may be bent backward, namely, in a direction opposite to a direction in which the at least a portion of the first area of the planar zone is visually exposed.

The planar zone may include the first area 510 corresponding to the display area and also include at least a portion of the second area 520 extending from the first area 510. The bending zone may include a bending area 530 extending from at least a portion of the second area 520. The bending zone may correspond to a portion of the display panel 450 that is bent as shown in FIG. 4.

The second area 520 may include a third area 532 and a fourth area 542. Herein, the third area 532 is defined as a region whose outline point (i.e., a first point 531) is spaced apart from the first area 510 by a first distance (A). Similarly, the fourth area 542 is defined as a region whose outline point (i.e., a second point 541) is spaced apart from the first area 510 by a second distance (B). The second point 541 may be more adjacent to the bending area 530 than the first point 531 is, and the second distance B may be less than the first distance A.

The second area 520 of the substrate may become narrower as approaching the bending area 530. In the second area 520, a portion adjacent to the bending area 530 may have an inwardly recessed outline.

At least one wiring layer for electrically connecting the DDI and the pixel layer may be disposed on the substrate.

The at least one wiring layer may be disposed on at least a portion of the planar zone and at least a portion of the bending zone. The at least one wiring layer may be formed starting from the first area corresponding to the display area of the planar zone, passing through the second area corresponding to the non-display area of the planar zone, and extending along the bending area of the bending zone. The at least one wiring layer may be formed from a portion of the second area to the bending area of the bending zone.

When a portion of the second area 520 adjacent to the bending area 530 is inwardly recessed at the outline, this may minimize a margin area required for the bending area to be bent and also widen the display area of the electronic device.

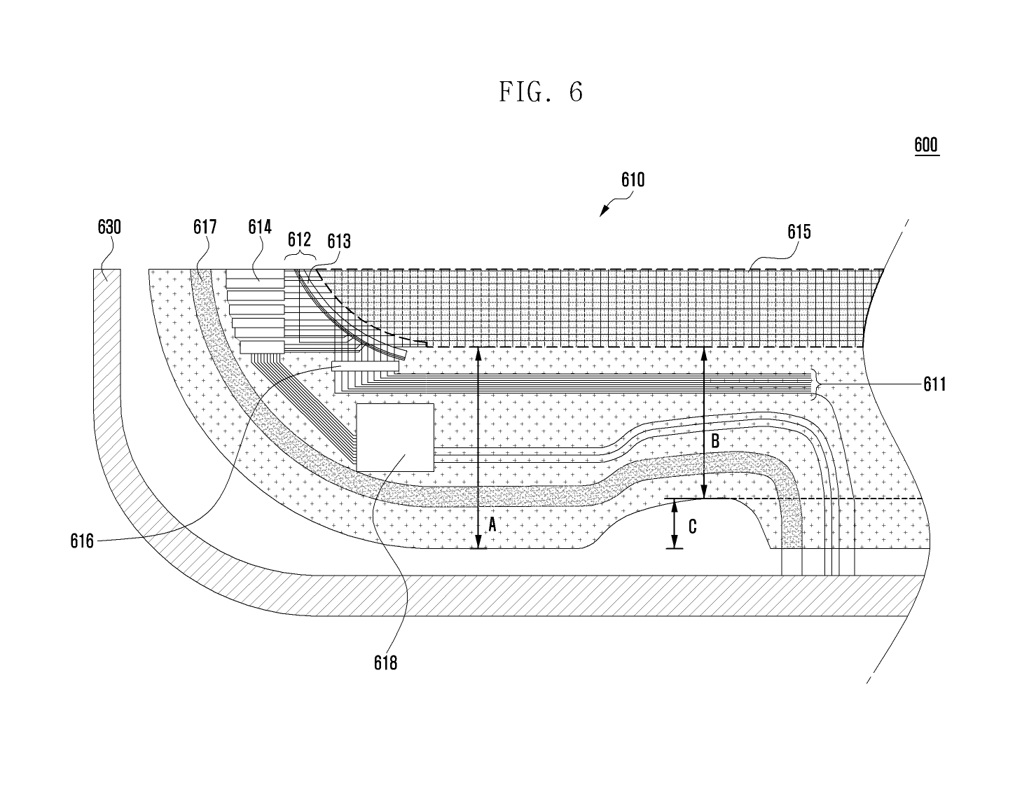

FIG. 6 is a diagram illustrating a left lower portion of an electronic device according to an embodiment.

The electronic device 600 may include a display panel 610 and a housing 630.

The display panel 610 may include a display area 615 in which a pixel layer including a plurality of pixels is disposed, and a non-display area that is an area other than the display area 615.

In the non-display area, various circuit elements and wiring layers may be disposed in order to supply a signal or power from a DDI to the pixel layer.

An ELVDD wiring layer 613 and an ELVSS wiring layer 617 both connected to a pixel power source to supply power to the pixel layer, EM blocks 614 including a gate driver and/or an emission driver, an electrical path 612 (e.g., a scan line, an EM line) starting from the gate driver and/or the emission driver, an electrical path 611 (e.g., a data line) starting from a source driver, other circuit element 616 including an ESD element, an ESD protection circuit 618, and the like may be disposed in the non-display area.

At least one corner of the electronic device 600 and at least one corner of the display panel 610 may be formed in a rounded rectangular shape.

When the at least one corner of the display panel 610 is formed in a rounded rectangular shape, circuit elements and wiring layers on the non-display area of the display panel 610 may be disposed to be adapted for the rounded rectangular shape.

In order to maximize the area of the display area 615 of the electronic device 600, the circuit elements and wiring layers disposed in the non-display area may have a predetermined size/width or less.

Among the circuit elements disposed in the non-display area, the EM blocks 614 including the gate driver and/or the emission driver may not be formed to have a predetermined size/width or less because the requirement for a driving current supplied from the EM blocks 614 may not be satisfied. On the other hand, the electrical path 612 (e.g., the scan line, the EM line) starting from the gate driver and/or the emission driver and the electrical path 611 (e.g., the data line) starting from the source driver may be formed to have a predetermined size/width or less without degradation in performance of the electronic device because signals supplied from such electrical paths 611 and 612 only need to maintain a specified voltage level regardless of the magnitude of a current.

In order to maximize the area of the display area 615 of the electronic device 600, the wiring width of the electrical path 612 starting from the gate driver and/or the emission driver of the display panel 610, that is, the wiring width of the scan line and/or the EM line may be reduced to a predetermined width or less. The wiring width of the electrical path 611 starting from the source driver, that is, the wiring width of the data line may be reduced.

By reducing the wiring width of at least some of the wiring layers disposed in the non-display area of the display panel 610, it is possible to reduce the area of the non-display area of the display panel 610.

As shown in FIG. 6, the display panel 610 may have a reduced distance from the outline of the display panel 610 to the display area 615 as approaching the bending zone of the display panel 610. The non-display area adjacent to the bending zone in the display panel 610 may be formed to have an inwardly recessed portion at the outline.

The display panel 610 may include a region whose outline point (the first point) is spaced apart from the display area 615 by the first distance (A), and a region whose outline point (the second point) is spaced apart from the display area 615 by the second distance (B).

As shown in FIG. 6, the second distance (B) may be shorter than the first distance (A), and the second point may be closer to the bending zone than the first point is. By reducing the wiring width of the electrical path 611 starting from the source driver, at least a portion of the non-display area adjacent to the bending zone in the display panel 610 may be formed to be inwardly recessed from the outline.

When the at least a portion of the non-display area adjacent to the bending zone is formed to be inwardly recessed from the outline, a bending start point of the bending zone may become closer to the display area 615.

The bending zone of the display panel 610 may be bent backward (that is, bent toward a direction opposite to a direction in which the at least a portion of the first area of the planar zone is visually exposed) from the bending start point which is one of outline points of the display panel 610 and has the shortest distance from the display area 615.

When a region adjacent to the bending zone in the display panel 610 is formed to have an inwardly recessed portion at the outline, the shortest distance of this region between the outline and the display area 615 is reduced from the first distance (A) to the second distance (B). That is, in this region, the non-display area is reduced by a distance difference (C) between the first and second distances.

When the non-display area of the display panel 610 adjacent to the bending zone is formed to have an inwardly recessed portion, the shortest distance from the bending start point to the display area is reduced and thus the width of the non-display area is reduced.

In order to form the non-display area of the display panel 610 adjacent to the bending zone to have an inwardly recessed portion, the electronic device 600 may have, at least in part, a multi-layer structure for the electrical path 612 (e.g., the scan line, the EM line) starting from the gate driver and/or the emission driver.

At least part of the scan line and/or the EM line may be formed in a process of forming a touch line of the touch panel disposed on the display panel 610. The at least part of the scan line and/or the EM line may be formed on the same layer as the touch line and thereby disposed in a multi-layer structure with the scan line and/or the EM line previously formed before the process of forming the touch line.

According to an embodiment, the electronic device may include a pixel layer including a plurality of pixels, a substrate including a first area in which the pixel layer is disposed, and a second area extending outward from the first area, a DDI configured to apply a signal to the pixel layer; and one or more wiring layers disposed on the substrate and electrically connected between the DDI and the pixel layer. In the electronic device, the substrate may include a planar zone including at least a portion of the first area and at least a portion of the second area, and a bending zone extending from the at least a portion of the second area, and the at least a portion of the second area may include a third area in which a first point of an outline of the planar zone is spaced apart from the first area by a first distance, and a fourth area in which a second point of the outline is spaced apart from the first area by a second distance being smaller than the first distance. In addition, a bending start point of the bending zone may be adjacent to the second point, and the one or more wiring layers may be disposed in at least a portion of the planar zone and at least a portion of the bending zone.

An outline of the first area may correspond to the outline of the planar zone and have a rounded rectangular shape in which at least one corner is formed of a curved line. In this case, an average radius of curvature of a curved line forming at least one corner of the outline of the planar zone may be greater than an average radius of curvature of the curved line forming the at least one corner of the outline of the first area.

The electronic device may further include a front plate disposed on the display. In this case, an outline of the front plate may correspond to the outline of the planar zone and have a rounded rectangular shape in which at least one corner is formed of a curved line. In addition, an average radius of curvature of the curved line forming the at least one corner of the outline of the front plate may be greater than an average radius of curvature of a curved line forming at least one corner of the outline of the planar zone.

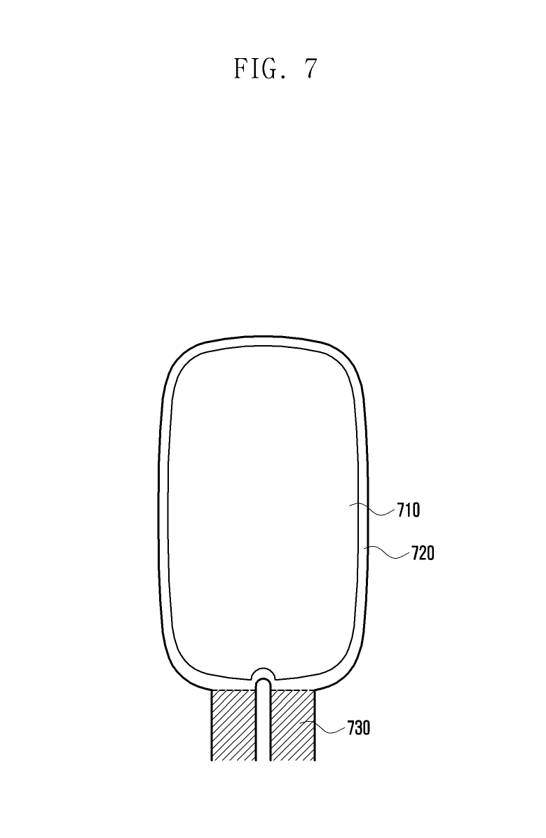

FIG. 7 is a diagram illustrating a display panel structure of an electronic device, according to an embodiment.

The display panel may include a pixel layer including a plurality of pixels and a substrate disposed under the pixel layer.

Referring to FIG. 7, the substrate of the display panel may include a first area 710 corresponding to a display area in which the pixel layer is disposed, and a second area 720 extending outward from the first area 710.

The substrate may include a planar zone and a bending zone. At least a portion (e.g., the bending zone) of the substrate may be bent. The substrate may be bent backward, that is, toward a direction opposite to a direction in which the at least a portion of the first area of the planar zone is visually exposed.

The planar zone may include, at least in part, the first area 710 corresponding to a region in which the pixel layer is disposed, and the second area 720 extending outwardly from the first area 710. The bending zone may include a bending area 730 extending from at least a portion of the second area 720. The bending zone may correspond to a bent region of the display panel 450 shown in FIG. 4.

As shown in FIG. 7, the bending zone may include a plurality of bending areas 730 spaced apart from each other.

The electronic device may include a plurality of DDIs, and the substrate of the display panel may include a plurality of bending areas 730 based on the positions of the plurality of DDIs.

The electronic device may include one DDI, which may be disposed to be in contact with all the plurality of bending areas 730 in a state where the plurality of bending areas 730 are bent toward a direction opposite to a direction in which the at least a portion of the first area of the planar zone is visually exposed.

The substrate of the display panel may be formed such that a portion adjacent to the bending zone in the second area 720 of the planar zone is formed to have an inwardly recessed portion. The second area 720 corresponding to a space between the plurality of bending areas 730 of the bending zone may be formed to have an inwardly recessed portion.

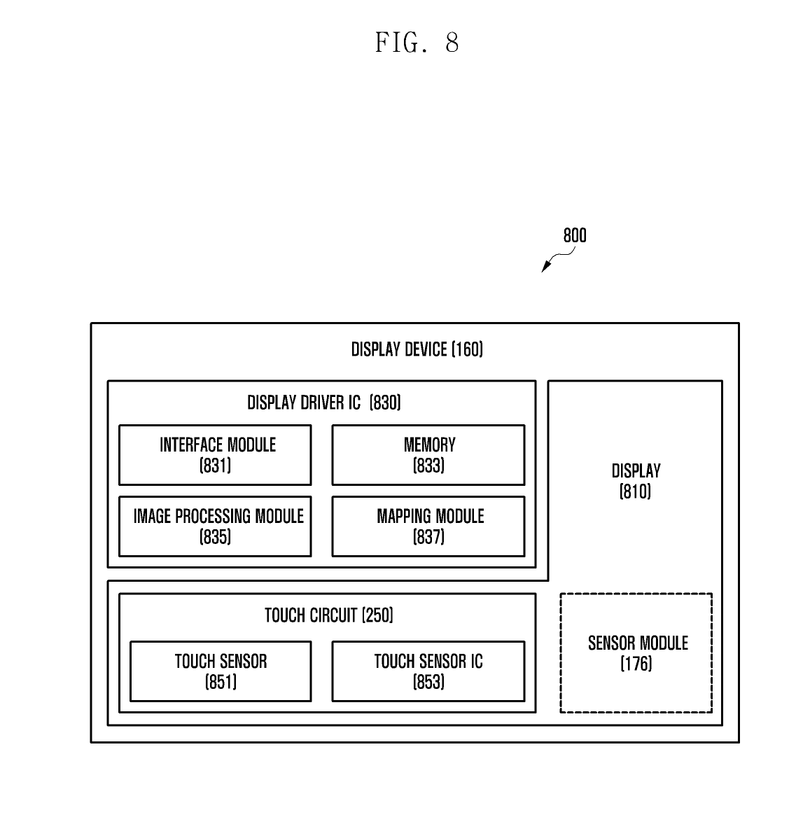

FIG. 8 is a block diagram 800 illustrating the display device 160 according to various embodiments. Referring to FIG. 8, the display device 160 may include a display 810 and a display driver integrated circuit (DDI) 830 to control the display 810. The DDI 830 may include an interface module 831, memory 833 (e.g., buffer memory), an image processing module 835, or a mapping module 837. The DDI 830 may receive image information that contains image data or an image control signal corresponding to a command to control the image data from another component of the electronic device 101 via the interface module 831. For example, the image information may be received from the processor 120 (e.g., the main processor 121 (e.g., an application processor)) or the auxiliary processor 123 (e.g., a graphics processing unit) operated independently from the function of the main processor 121. The DDI 830 may communicate, for example, with touch circuitry 150 or the sensor module 176 via the interface module 831. The DDI 830 may also store at least part of the received image information in the memory 833, for example, on a frame by frame basis.

The image processing module 835 may perform pre-processing or post-processing (e.g., adjustment of resolution, brightness, or size) with respect to at least part of the image data. The pre-processing or post-processing may be performed, for example, based at least in part on one or more characteristics of the image data or one or more characteristics of the display 810.

The mapping module 837 may generate a voltage value or a current value corresponding to the image data pre-processed or post-processed by the image processing module 835. The generating of the voltage value or current value may be performed, for example, based at least in part on one or more attributes of the pixels (e.g., an array, such as an RGB stripe or a pentile structure, of the pixels, or the size of each subpixel). At least some pixels of the display 810 may be driven, for example, based at least in part on the voltage value or the current value such that visual information (e.g., a text, an image, or an icon) corresponding to the image data may be displayed via the display 810.

The display device 160 may further include the touch circuitry 850. The touch circuitry 850 may include a touch sensor 851 and a touch sensor IC 853 to control the touch sensor 851. The touch sensor IC 853 may control the touch sensor 851 to sense a touch input or a hovering input with respect to a certain position on the display 810. To achieve this, for example, the touch sensor 851 may detect (e.g., measure) a change in a signal (e.g., a voltage, a quantity of light, a resistance, or a quantity of one or more electric charges) corresponding to the certain position on the display 810. The touch circuitry 850 may provide input information (e.g., a position, an area, a pressure, or a time) indicative of the touch input or the hovering input detected via the touch sensor 851 to the processor 120. At least part (e.g., the touch sensor IC 853) of the touch circuitry 850 may be formed as part of the display 810 or the DDI 830, or as part of another component (e.g., the auxiliary processor 123) disposed outside the display device 160.

The display device 160 may further include at least one sensor (e.g., a fingerprint sensor, an iris sensor, a pressure sensor, or an illuminance sensor) of the sensor module 176 or a control circuit for the at least one sensor. In such a case, the at least one sensor or the control circuit for the at least one sensor may be embedded in one portion of a component (e.g., the display 810, the DDI 830, or the touch circuitry 150)) of the display device 160. For example, when the sensor module 176 embedded in the display device 160 includes a biometric sensor (e.g., a fingerprint sensor), the biometric sensor may obtain biometric information (e.g., a fingerprint image) corresponding to a touch input received via a portion of the display 810. As another example, when the sensor module 176 embedded in the display device 160 includes a pressure sensor, the pressure sensor may obtain pressure information corresponding to a touch input received via a partial or whole area of the display 810. The touch sensor 851 or the sensor module 176 may be disposed between pixels in a pixel layer of the display 810, or over or under the pixel layer.

The electronic device according to various embodiments may be one of various types of electronic devices. The electronic devices may include, for example, a portable communication device (e.g., a smart phone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and do not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

A method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to certain embodiments thereof, it will be understood by those skilled in the art that various changes in form and details may be made therein without departing from the scope of the disclosure. Therefore, the scope of the disclosure should not be defined as being limited to the embodiments, but should be defined by the appended claims and equivalents thereof.

What is claimed is:

1. An electronic device comprising:
a pixel layer including a plurality of pixels;
a substrate including a first area in which the pixel layer is disposed, and a second area extending outward from the first area;
a display driver integrated circuit (DDT) configured to apply a signal to the pixel layer; and
one or more wiring layers disposed on the substrate and electrically connected between the DDI and the pixel layer,
wherein the substrate includes a planar zone including at least a portion of the first area and at least a portion of the second area, and a bending zone extending from the at least a portion of the second area,
wherein the at least a portion of the second area includes a third area in which a first point of an outline of the planar zone is spaced apart from the first area by a first distance, and a fourth area in which a second point of the outline is spaced apart from the first area by a second distance being smaller than the first distance,
wherein a bending start point of the bending zone is adjacent to the second point, and
wherein the one or more wiring layers are disposed in at least a portion of the planar zone and at least a portion of the bending zone.

2. The electronic device of claim 1, wherein the outline of the planar zone has a rounded rectangular shape in which at least one corner is formed of a curved line.

3. The electronic device of claim 1, wherein the DDI includes at least one of a gate driver or an emission driver, and
wherein the second area has an electrical path starting from at least one of the gate driver or the emission driver.

4. The electronic device of claim 3, further comprising:
a touch panel formed on the substrate,
wherein the electrical path starting from at least one of the gate driver or the emission driver is formed, at least in part, on a same plane as the touch panel.

5. The electronic device of claim 3, wherein the electrical path starting from at least one of the gate driver or the emission driver is disposed, at least in part, in a multi-layer structure in the second area.

6. The electronic device of claim 1, wherein the DDI includes a source driver, and
wherein the second area has an electrical path starting from the source driver.

7. The electronic device of claim 1, wherein at least a portion of the bending zone is bent toward a direction opposite to a direction in which the at least a portion of the first area of the planar zone is visually exposed.

8. The electronic device of claim 1, wherein the DDI is disposed in the bending zone.

9. The electronic device of claim 1, further comprising:
a printed circuit board (PCB) electrically coupled to the substrate,
wherein the DDI is disposed on the PCB.

10. The electronic device of claim 9, wherein the DDI includes a plurality of DDIs.

11. The electronic device of claim 1, wherein the display includes an organic light emitting diode.

12. The electronic device of claim 1, wherein the bending zone includes a plurality of areas spaced apart from each other.

13. The electronic device of claim 1, wherein an outline of the first area corresponds to the outline of the planar zone and has a rounded rectangular shape in which at least one corner is formed of a curved line, and
wherein an average radius of curvature of a curved line forming at least one corner of the outline of the planar zone is greater than an average radius of curvature of the curved line forming the at least one corner of the outline of the first area.

14. The electronic device of claim 1, further comprising:
a front plate disposed on the display,
wherein an outline of the front plate corresponds to the outline of the planar zone and has a rounded rectangular shape in which at least one corner is formed of a curved line, and
wherein an average radius of curvature of the curved line forming the at least one corner of the outline of the front plate is greater than an average radius of curvature of a curved line forming at least one corner of the outline of the planar zone.

15. An electronic device comprising:
a display panel; and
a touch panel formed on the display panel,
wherein the display panel comprises:
a pixel layer including a plurality of pixels;
a substrate including a first area in which the pixel layer is disposed, and a second area extending outward from the first area;
a display driver integrated circuit (DDI) configured to apply a signal to the pixel layer; and
one or more wiring layers disposed on the substrate and electrically connected between the DDI and the pixel layer,
wherein the substrate includes a planar zone including at least a portion of the first area and at least a portion of the second area, and a bending zone extending from the at least a portion of the second area,
wherein the at least a portion of the second area includes a third area in which a first point of an outline of the planar zone is spaced apart from the first area by a first distance, and a fourth area in which a second point of the outline is spaced apart from the first area by a second distance being smaller than the first distance,
wherein a bending start point of the bending zone is adjacent to the second point, and
wherein the one or more wiring layers are disposed in at least a portion of the planar zone and at least a portion of the bending zone.

16. The electronic device of claim 15, wherein the DDI includes at least one of a gate driver or an emission driver, and
wherein an electrical path starting from at least one of the gate driver or the emission driver is formed in the second area of the display panel.

17. The electronic device of claim 16, wherein at least a portion of the electrical path starting from at least one of the gate driver or the emission driver is formed on a same plane as the touch panel, and electrically coupled to the electrical path starting from at least one of the gate driver or the emission driver and formed in the second area of the display panel.

18. The electronic device of claim 17, wherein the at least a portion of the electrical path starting from at least one of the gate driver or the emission driver and formed on a same plane as the touch panel is formed on a same plane as the touch panel corresponding to a region where the electrical path starting from at least one of the gate driver or the emission driver is formed in the second area of the display panel.

19. The electronic device of claim 16, wherein the DDI includes a source driver, and
wherein an electrical path starting from the source driver is formed in the second area.

20. The electronic device of claim 15, wherein at least a portion of the bending zone is bent toward a direction opposite to a direction in which the at least a portion of the first area of the planar zone is visually exposed.
